(19) United States
(12) Patent Application Publication
(10) Pub. No.: US 2011/0284056 A1
(43) Pub. Date: Nov. 24, 2011

(54) SOLAR CELL HAVING REDUCED LEAKAGE CURRENT AND METHOD OF MANUFACTURING THE SAME

(76) Inventors: Jung-Eun LEE, Goyang-si (KR); Ku-Hyun Kang, Suwon-si (KR)

(21) Appl. No.: 13/088,107

(22) Filed: Apr. 15, 2011

(30) Foreign Application Priority Data
May 24, 2010 (KR) 10-2010-0048151

(51) Int. Cl. H01L 31/042; H01L 31/0224

(52) U.S. Cl. 136/249; 438/73; 257/E31.126

(57) ABSTRACT

A solar cell having a reduced leakage current and a method for fabricating the same are provided. The solar cell includes a plurality of solar cells, and a plurality of cell division parts dividing each of the plurality of solar cells. Each of the plurality of solar cells includes a transparent electrode layer formed on a substrate, a first photoelectric conversion layer formed on the transparent electrode layer, an interlayer formed on the first photoelectric conversion layer, first and second division parts in which the interlayer is substantially absent, and a second photoelectric conversion layer formed on the interlayer. The cell division parts are formed within their respective second division parts.

### CROSS-REFERENCE TO RELATED APPLICATION

This application claims priority from Korean Patent Application No. 10-2010-0048151 filed on May 24, 2010 in the Korean Intellectual Property Office, the disclosure of which is incorporated herein by reference in its entirety.

### BACKGROUND OF THE INVENTION

1. Field of the Invention

The present invention relates generally to solar cells. More specifically, the present invention relates to solar cells having reduced leakage current.

2. Description of the Related Art

Solar cells, also known as photovoltaic cells, are elements formed using, for example, semiconductor p-n junctions which directly convert radiant energy from the sun into electrical energy.

The p-n junction solar cell is based on the phenomenon by which, when sunlight having higher energy than semiconductor band-gap energy (Eg) is incident onto a solar cell, electron-hole pairs are generated inside the semiconductor p-n junctions. That is to say, the p-n junction solar cell uses electric power generated between the p-n junctions when the electron-hole pairs are released by incident sunlight, and electrons and holes of the generated electron-hole pairs are collected in n-type and p-type semiconductor layers, respectively, by electric fields formed in the p-n junctions.

Meanwhile, a variety of attempts to investigate internal structures of the solar cell are being made in order to improve solar cell efficiency. One such structure, employing an interlayer formed between a first photoelectric conversion layer and a second photoelectric conversion layer, has been proposed to improve solar cell efficiency. This proposed structure, however, has a problem of current leakage, which may occur when the remainder of a lower transparent electrode layer is shunted to the interlayer during fabrication.

### SUMMARY OF THE INVENTION

The present invention provides a solar cell having a reduced leakage current.

The present invention also provides a method for fabricating a solar cell having a reduced leakage current.

The above and other objects of the present invention will be described in or be apparent from the following description of the preferred embodiments.

According to an aspect of the present invention, there is provided a solar cell including a plurality of solar cells, and a plurality of cell division parts dividing each of the plurality of solar cells. Each of the plurality of solar cells includes a transparent electrode layer formed on a substrate, a first photoelectric conversion layer formed on the transparent electrode layer, an interlayer formed on the first photoelectric conversion layer, first and second division parts in which the interlayer is substantially absent, and a second photoelectric conversion layer formed on the interlayer. The cell division parts are formed within their respective second division parts.

According to another aspect of the present invention, there is provided a method for fabricating a solar cell, the method including forming a transparent electrode layer on a substrate, forming a first photoelectric conversion layer on the transparent electrode layer, and forming an interlayer on the first photoelectric conversion layer. Also included is forming first and second division parts by patterning the interlayer, the interlayer being substantially removed in the first and second division parts, forming a second photoelectric conversion layer on the interlayer, and forming a third division part by patterning the first and second photoelectric conversion layers. The method also includes forming a cell division part within the second division part by patterning the transparent electrode layer, and the first and second photoelectric conversion layers.

### BRIEF DESCRIPTION OF THE DRAWINGS

The above and other features and advantages of the present invention will become more apparent by describing in detail preferred embodiments thereof with reference to the attached drawings in which:

FIG. 1 is a cross-sectional view of a solar cell according to an aspect of the inventive concept of the present invention;

FIG. 2 is an enlarged view of an “A” portion of FIG. 1; and

FIGS. 3 through 10 are cross-sectional views illustrating intermediate process steps in a method for fabricating a solar cell according to an aspect of the inventive concept of the present invention.

### DETAILED DESCRIPTION OF THE INVENTION

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. In the drawings, the size and relative sizes of layers and regions may be exaggerated for clarity. It will be understood that when an element is referred to as being “on” another element, it can be directly on the other element or intervening elements may be present therebetween. In contrast, when an element is referred to as being “directly on” another element, there are no intervening elements present.

Like reference numerals refer to like elements throughout the specification. As used herein, the term “and/or” includes any and all combinations of one or more of the associated listed items.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Embodiments described herein will be described referring to plan views and/or cross-sectional views by way of ideal schematic views of the invention. Accordingly, the exemplary views may be modified depending on manufacturing technologies and/or tolerances. Therefore, the embodiments of the invention are not limited to those shown in the views, but include modifications in configuration formed on the basis of manufacturing processes. Therefore, regions exemplified in figures have schematic properties and shapes of regions shown in figures exemplify specific shapes of regions of elements and not limit aspects of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

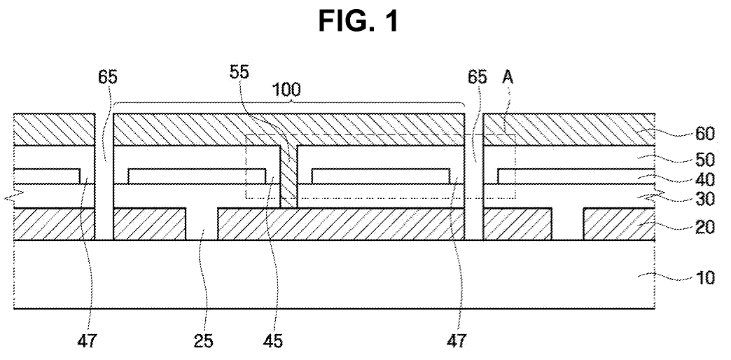

Hereinafter, a solar cell according to an aspect of the inventive concept of the present invention will be described in further detail with reference to the accompanying drawings. FIG. 1 is a cross-sectional view of a solar cell according to an aspect of the inventive concept of the present invention.

Referring to FIG. 1, the solar cell may include a plurality of solar cells 100 and a plurality of cell division parts 65 dividing the solar cells 100.

Each of the solar cells 100 may include a substrate 10, a transparent electrode layer 20, a first photoelectric conversion layer 30, an interlayer 40, a second photoelectric conversion layer 50, and a back surface electrode layer 60.

The substrate 10 is a base element of a solar cell and is generally made of an insulating material such as glass. In particular, soda lime glass is preferably used as the substrate 10 for some applications, as soda lime glass is often low-cost and, as is known, Na ions in the soda lime glass can act to improve solar cell efficiency. Alternatively, the substrate 10 may be formed of a ceramic substrate made of alumina. The substrate 10 may also be made of stainless steel coated with an insulating material, or a flexible polymer.

A transparent electrode layer 20 may be formed on the substrate 10. Since the transparent electrode layer 20 allows charges generated from the solar cell to flow outside, it may be made of a transparent conductive oxide (TCO) having relatively low contact resistance. Examples of the TCO may include SnO₂, ZnO, ITO, BZO, and so on.

In the solar cell 100 according to an aspect of the inventive concept of the present invention, the transparent electrode layer 20 may include a fourth division part 25, as shown in FIG. 1. The fourth division part 25 is filled with the first photoelectric conversion layer 30, which is further described below.

The first photoelectric conversion layer 30 may be formed on the transparent electrode layer 20. The first photoelectric conversion layer 30 may be a photoelectric conversion layer made of, for example, amorphous silicon (a-Si). In addition, although not shown in FIG. 1, the first photoelectric conversion layer 30 may have a structure in which a first-conductivity type semiconductor layer, an a-Si layer, and a second-conductivity type semiconductor layer are sequentially stacked, but aspects of the inventive concept of the present invention are not limited thereto. Any suitable layer or set of layers is contemplated. The first photoelectric conversion layer 30 may have various structures, including a-Si. As described above, the first photoelectric conversion layer 30 may fill the fourth division part 25.

The interlayer 40 may be formed on the first photoelectric conversion layer 30. The interlayer 40 may be made of a light-transmitting and light-reflecting material, e.g. a material that both reflects and transmits light. Examples of the light-transmitting and light-reflecting material may include SnO₂, ZnO, ITO, BZO, and so on.

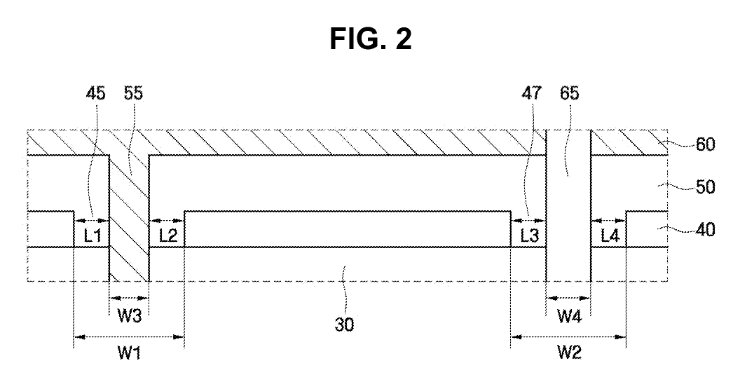

As shown in FIG. 1, a first division part 45 and a second division part 47 may be formed on the interlayer 40. The first division part 45 may be formed to overlap a third division part 55 to be described later, and the second division part 47 may be formed to overlap the cell division part 65, which will later be described in more detail with reference to FIG. 2.

The second photoelectric conversion layer 50 may be formed on the interlayer 40. As shown in FIG. 1, the second photoelectric conversion layer 50 may be formed in at least portions of the first division part 45 and the second division part 47 of the interlayer 40. Meanwhile, the second photoelectric conversion layer 50 may be a photoelectric conversion layer made of, for example, amorphous silicon (a-Si). Although not shown in FIG. 1, the second photoelectric conversion layer 50 may have a structure in which a first-conductivity type semiconductor layer, a crystalline Si layer, and a second-conductivity type semiconductor layer are sequentially stacked, but aspects of the inventive concept of the present invention are not limited thereto. The second photoelectric conversion layer 50 may have various structures, and any suitable layer or set of layers is contemplated.

The back surface electrode layer 60 may be formed on the second photoelectric conversion layer 50. The back surface electrode layer 60 may function not only as an electrode layer but also as a light reflecting layer. The back surface electrode layer 60 may be made of, for example, Ag or Al. The back surface electrode layer 60 may be formed while filling the third division part 55, as shown in FIG. 1.

Next, structures of the division parts 45, 47, 55, and 65 in the solar cell according to the aspect of the inventive concept of the present invention will be described.

FIG. 2 is an enlarged view of the portion “A” of FIG. 1.

Referring to FIG. 2, the third division part 55 formed in the first photoelectric conversion layer 30 and the second photoelectric conversion layer 50 may also be formed within the first division part 45 of the interlayer 40. That is to say, the third division part 55 may be formed to overlap the first division part 45, where a width W3 of the third division part 55 is smaller than a width W1 of the first division part 45. More specifically, the third division part 55 may be formed within the first division part 45, such that a distance L1 between one side wall of the first division part 45 and one side wall of the third division part 55 may be equal to a distance L2 between the other side wall of the first division part 45 and the other side wall of the third division part 55, as shown in FIG. 2.

Meanwhile, the transparent electrode layer 20, the first photoelectric conversion layer 30, the second photoelectric conversion layer 50, and the cell division part 65 formed on the back surface electrode layer 60 may be formed within the second division part 47 of the interlayer 40. That is to say, the cell division part 65 may be formed to overlap the second division part 47, where a width W4 of the cell division part 65 is smaller than a width W2 of the second division part 47. More specifically, as shown in FIG. 2, the cell division part 65 may be formed within the second division part 47 such that a distance L3 between one side wall of the second division part 47 and one side wall of the cell division part 65 may be equal to a distance L4 between the other side wall of the second division part 47 and the other side wall of the cell division part 65.

As described above, FIG. 2 illustrates that the distance L1 between one side wall of the first division part 45 and one side wall of the third division part 55 is equal to the distance L2 between the other side wall of the first division part 45 and the other side wall of the third division part 55, and that the distance L3 between one side wall of the second division part 47 and one side wall of the cell division part 65 is equal to the distance L4 between the other side wall of the second division part 47 and the other side wall of the cell division part 65. However, aspects of the inventive concept of the present invention are not limited thereto. That is to say, in a solar cell according to another aspect of the inventive concept of the present invention, the distances L1 and L2 may or may not be equal to each other, and likewise the distances L3 and L4 may or may not be equal to each other.

As above, the cell division part 65 may be formed within the second division part 47, and the third division part 55 may be formed within the first division part 45. Therefore, even if a portion of the transparent electrode layer 20 is removed during formation of the cell division part 65 or the third division part 55, the transparent electrode layer 20 is unlikely to be shunted to the interlayer 40, thereby preventing current leakage, which may occur when the interlayer 40 is shunted to the transparent electrode layer 20. That is, since the parts 55, 65 are formed in regions in which the second photoelectric conversion layer 50 surrounds and protects interlayer 40, formation of parts 55, 65 does not result in any removed part of transparent electrode layer 20 contacting interlayer 40. In other words, as the interlayer 40 is substantially absent in the first and second division parts 45, 47 (having been removed from those areas prior to deposition of the second photoelectric conversion layer 50 in those areas), and those division parts 45, 47 are instead filled by the second photoelectric conversion layer 50, the fabrication of cell division parts 65 and third division part 55 does not result in any unwanted conductive material contacting interlayer 40.

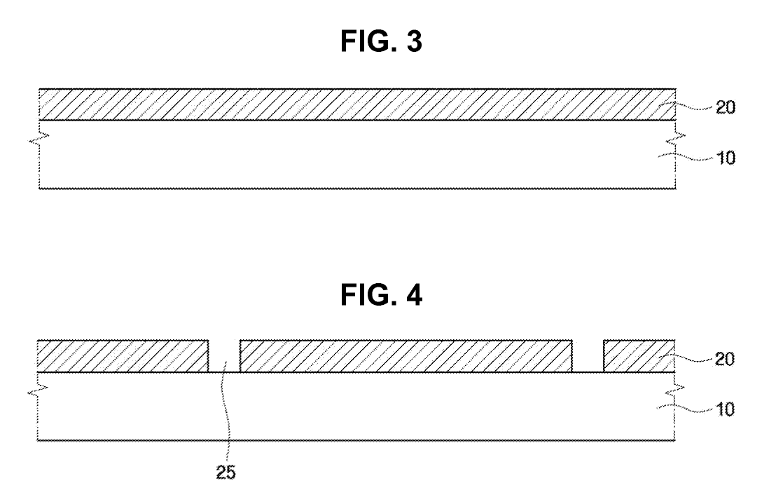

A method for fabricating a solar cell according to an aspect of the inventive concept of the present invention will now be described with reference to FIGS. 3 through 10.

FIGS. 3 through 10 are cross-sectional views illustrating intermediate process steps in a method for fabricating a solar cell according to an aspect of the inventive concept of the present invention. In the following, repetitive descriptions of functional components, including the material and configuration of each component, which have already been described in the previous embodiment of the solar cell shown in FIGS. 1 and 2 will be omitted.

Referring first to FIG. 3, a transparent electrode layer 20 is formed on a substrate 10. Here, the transparent electrode layer 20 may be deposited on the substrate 10 by, for example, low pressure chemical vapor deposition (LPCVD). The transparent electrode layer 20 may be formed to a thickness in the range of approximately 1 to 2 μm.

Referring to FIG. 4, the transparent electrode layer 20 is patterned to form a fourth division part 25. The fourth division part 25 may be formed by irradiating patterning light, e.g., laser light, on one surface of the transparent electrode layer 20. Here, a width of the fourth division part 25 may be in the range of about 50 to 150 μm.

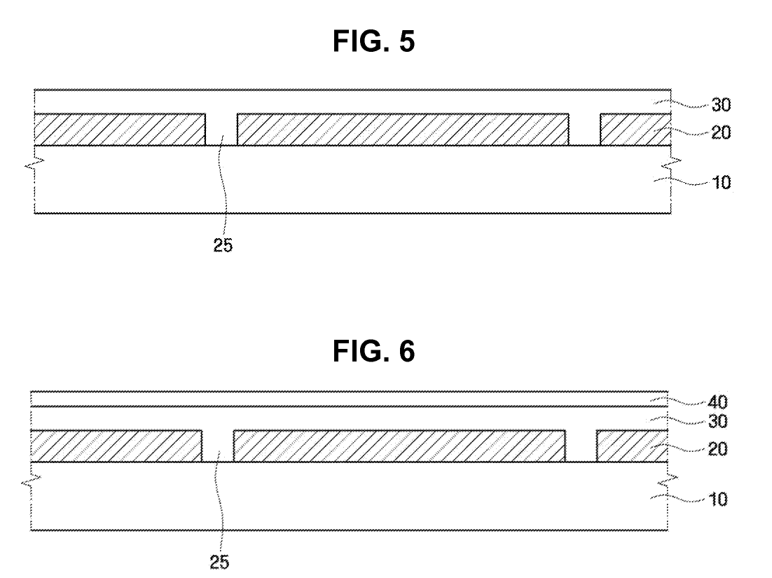

Referring to FIG. 5, a first photoelectric conversion layer 30 may be formed on the transparent electrode layer 20. Here, the first photoelectric conversion layer 30 may be deposited on the transparent electrode layer 20 by, for example, chemical vapor deposition (CVD). Meanwhile, the first photoelectric conversion layer 30 may be formed to fill the fourth division part 25 formed on the transparent electrode layer 20, as shown in FIG. 5.

Next, referring to FIG. 6, an interlayer 40 may be formed on the first photoelectric conversion layer 30. The interlayer 40 may be formed on the first photoelectric conversion layer 30 to a thickness in a range of about 250 to 500 Å by, for example, LPCVD.

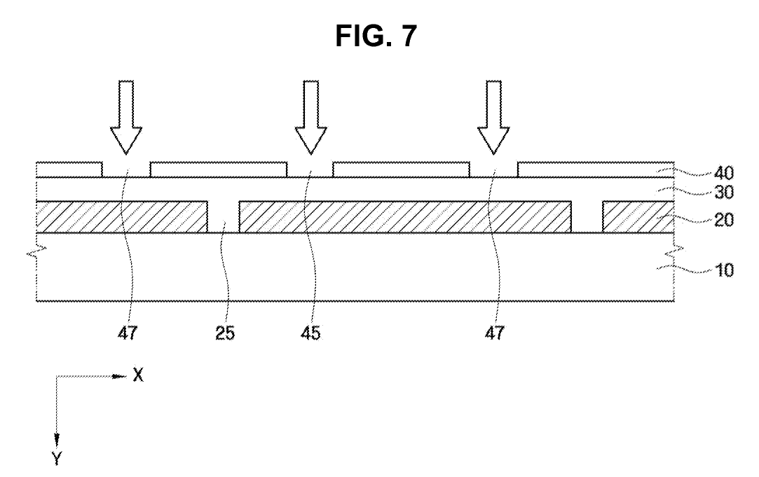

Referring to FIG. 7, the interlayer 40 is patterned to form a first division part 45 and a second division part 47. The first division part 45 and the second division part 47 may be formed by irradiating patterning light on the upper surface of the interlayer 40. That is to say, the patterning light is irradiated in the Y-direction in the embodiment illustrated in FIG. 7, thereby forming the first division part 45 and the second division part 47 on the interlayer 40. This patterning process forms the first division part 45 and the second division part 47 by substantially removing the interlayer 40 in those areas. That is, the first division part 45 and the second division part 47 are those areas in which the interlayer 40 has been removed, and is thus substantially absent.

In this case, the patterning light may be, for example, UV laser light. Specifically, the patterning light may be UV laser light having a wavelength in the range of, for example, about 300 to 400 μm. More specifically, the patterning light may be UV laser light having a wavelength of, for example, approximately 300 μm. If the wavelength of the UV laser light is smaller than about 300 μm, the interlayer 40 may not be completely, or properly, patterned. However, if the wavelength of the UV laser light is greater than about 400 μm, the irradiation of the UV laser light may cause damage to the first photoelectric conversion layer 30.

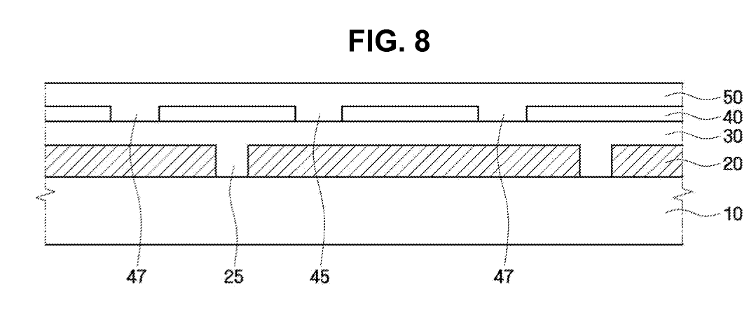

Referring to FIG. 8, a second photoelectric conversion layer 50 may be formed on the interlayer 40. Here, the second photoelectric conversion layer 50 may be deposited on the interlayer 40 by, for example, chemical vapor deposition (CVD). Meanwhile, the second photoelectric conversion layer 50 may be formed to fill the first division part 45 and the second division part 47, as shown in FIG. 8.

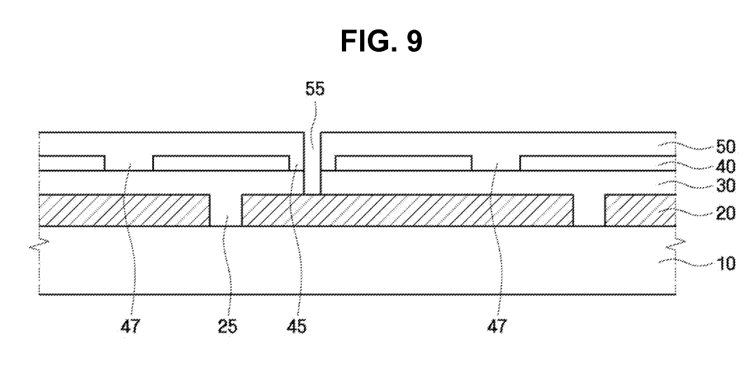

Referring to FIG. 9, the first photoelectric conversion layer 30 and the second photoelectric conversion layer 50 are patterned to form a third division part 55. The third division part 55 may be formed by irradiating patterning light, e.g., laser light, on one surface of the second photoelectric conversion layer 50. Here, a width of the third division part 55 according to the aspect of the inventive concept of the present invention may be smaller than that of the first division part 45, as shown in FIG. 9. In detail, the third division part 55 may be formed within the first division part 45. With this configuration, even if a portion of the transparent electrode layer 20 is removed during patterning of the third division part 55, the transparent electrode layer 20 is unlikely to be shunted to the interlayer 40, thereby preventing current leakage which may occur when the interlayer 40 is shunted to the transparent electrode layer 20.

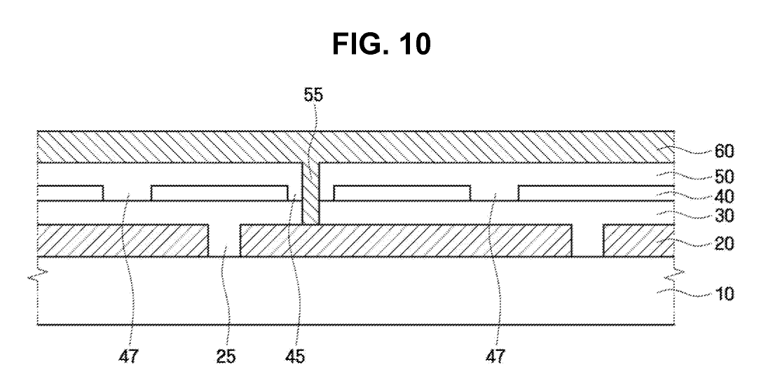

Next, referring to FIG. 10, a back surface electrode layer 60 may be formed on the second photoelectric conversion layer 50. The back surface electrode layer 60 may be formed on the second photoelectric conversion layer 50 by, for example, sputtering. Forming the back surface electrode layer 60 may include filling the third division part 55, as shown in FIG. 10. Accordingly, the third division part 55 filled with the back surface electrode layer 60 may function as a contact of the solar cell.

Referring back to FIG. 1, the transparent electrode layer 20, the first and second photoelectric conversion layers 30 and 50, and the back surface electrode layer 60 are patterned to form the cell division part 65. The cell division part 65 may be formed by irradiating patterning light, e.g., laser light, on one surface of the back surface electrode layer 60. As shown in FIG. 1, a width of the cell division part 65 according to the aspect of the inventive concept of the present invention may be smaller than that of the second division part 47. In detail, the cell division part 65 may be formed within the second division part 47. With this configuration, even if the remainder of the transparent electrode layer 20 is evaporated while patterning the cell division part 65, the transparent electrode layer 20 is unlikely to be shunted to the interlayer 40, thereby preventing current leakage in the solar cell.

While the present invention has been particularly shown and described with reference to exemplary embodiments thereof, it will be understood by those of ordinary skill in the art that various changes in form and details may be made therein without departing from the spirit and scope of the present invention as defined by the following claims. It is therefore desired that the present embodiments be considered in all respects as illustrative and not restrictive, reference being made to the appended claims rather than the foregoing description to indicate the scope of the invention.

What is claimed is:

1. A solar cell comprising:
a plurality of solar cells; and a plurality of cell division parts dividing each of the plurality of solar cells;
wherein each of the plurality of solar cells includes:
a transparent electrode layer formed on a substrate;
a first photoelectric conversion layer formed on the transparent electrode layer;
an interlayer formed on the first photoelectric conversion layer;
first and second division parts in which the interlayer is substantially absent; and
a second photoelectric conversion layer formed on the interlayer; and
wherein the cell division parts are formed within their respective second division parts.

2. The solar cell of claim 1, wherein the first photoelectric conversion layer and the second photoelectric conversion layer include a third division part overlapping the first division part.

3. The solar cell of claim 2, wherein a width of the third division part is smaller than a width of the first division part.

4. The solar cell of claim 2, wherein the third division part is formed within the first division part.

5. The solar cell of claim 2, wherein the solar cell further comprises a back surface electrode layer formed on the second photoelectric conversion layer, wherein the back surface electrode layer is formed while filling the third division part.

6. The solar cell of claim 1, wherein the second photoelectric conversion layer fills at least portions of the first and second division parts.

7. The solar cell of claim 1, wherein the transparent electrode layer includes a fourth division part.

8. The solar cell of claim 7, wherein the first photoelectric conversion layer fills the fourth division part.

9. A method for fabricating a solar cell, comprising:
forming a transparent electrode layer on a substrate;
forming a first photoelectric conversion layer on the transparent electrode layer;
forming an interlayer on the first photoelectric conversion layer
forming first and second division parts by patterning the interlayer, the interlayer being substantially removed in the first and second division parts;
forming a second photoelectric conversion layer on the interlayer;
forming a third division part by patterning the first and second photoelectric conversion layers; and
forming a cell division part within the second division part by patterning the transparent electrode layer, and the first and second photoelectric conversion layers.

10. The method of claim 9, wherein the forming of the first and second division parts further comprises irradiating a patterning light upon the interlayer.

11. The method of claim 10, wherein the patterning light comprises ultraviolet (UV) laser light.

12. The method of claim 11, wherein a wavelength of the UV laser light is in the range of about 300 to 400/μm.

13. The method of claim 9, wherein the forming of the second photoelectric conversion layer further comprises filling the first and second division parts with the second photoelectric conversion layer.

14. The method of claim 13, wherein the third division part is formed within the first division part by patterning the first photoelectric conversion layer and the second photoelectric conversion layer.

15. The method of claim 14, wherein a distance between one side wall of the first division part and one side wall of the third division part is substantially equal to a distance between another side wall of the first division part and another side wall of the third division part.

16. The method of claim 13, wherein the forming cell division parts further comprises patterning the transparent electrode layer, the first photoelectric conversion layer, the second photoelectric conversion layer filling the second division part, and the back surface electrode layer.

17. The method of claim 16, wherein a distance between one side wall of the second division part and one side wall of the cell division part is substantially equal to a distance between another side wall of the second division part and another side wall of the cell division part.

18. The method of claim 9, further comprising forming a back surface electrode layer on the second photoelectric conversion layer, so as to fill the third division part with the back surface electrode layer.

19. The method of claim 9, further comprising forming a fourth division part by patterning the transparent electrode layer.

20. The method of claim 19, wherein the forming of the first photoelectric conversion layer on the transparent electrode layer comprises filling the fourth division part with the first photoelectric conversion layer.
